(19) United States
(12) Patent Application Publication
(10) Pub. No.: US 2021/0007070 A1
(43) Pub. Date: Jan. 7, 2021

(54) AUTO FIELD CALIBRATION ERROR DETECTION AND RECOVERY

(71) Applicant: QUALCOMM Incorporated, San Diego, CA (US)

(72) Inventors: Surendra Kompala, Hyderabad (IN); Uday Kumar Kuppili, Hyderabad (IN); Stanley Tsai, Frederick, CO (US); Rahul Jaitly, Hyderabad (IN); Troy Curtiss, Boulder, CO (US); Naga Chandan Babu Gudivada, Hyderabad (IN); Ehren Van Melle, Longmont, CO (US)

(21) Appl. No.: 16/574,836

(22) Filed: Sep. 18, 2019

(30) Foreign Application Priority Data
Jul. 4, 2019 (IN) 201921026806

(51) Int. Cl. H04W 56/00; H04M 1/725; H03L 1/02

(52) U.S. Cl. CPC H04W 56/002; H04W 56/0035; H04M 2242/20; H03L 1/02; H04M 1/72522

(57) ABSTRACT

Auto-recovery from RF signal acquisition failure may be provided in a portable computing device. A field-calculated frequency-temperature (“FT”) curve is used to apply temperature compensation to a crystal oscillator associated with RF transceiver circuity of the device. In response to acquisition failure, it may be determined whether a deviation between the field-calculated FT curve and a factory-set FT curve exceeds threshold criteria. In response to acquisition success, the field-calculated FT curve may be refined based on frequency error information. However, in response to acquisition failure and a determination that the deviation exceeds the threshold criteria, information defining the field-calculated FT curve may be replaced with information defining the factory-set FT curve.

### DESCRIPTION OF THE RELATED ART

Crystal oscillator (“XO”) frequency accuracy is defined in terms of parts per million (“ppm”) and provides a convenient way of comparing accuracies of different XO specifications. For example, an XO of the type commonly used in timekeeping devices may have an error of 100 ppm, which translates as 100/1e⁶ or 1e⁻⁴ in exponential notation. Accordingly, such an XO may contribute a total daily error of 86400×1e⁻⁴ or 8.64 seconds per day.

Crystal oscillators are also used as a basis for generating signals having accurate frequencies in radio frequency (“RF”) transceivers, such as a transceiver of a mobile phone or other portable computing device (“PCD”). It is well known that temperature can significantly impact the accuracy of an XO. Because mobile phone transceivers require accurate frequencies for proper operation, temperature compensation is commonly employed. The oscillation frequency of an XO may be adjusted in response to temperature measurements and an equation or function known as a frequency-temperature (“FT”) curve. An XO manager or controller in the phone may supply the FT curve to the XO. An initial FT curve is commonly defined or set at the time the mobile phone is manufactured and then refined by further calculations during operation of the mobile phone by end-users under routine circumstances and in routine environments, i.e., “in the field,” as the phone experiences a wider range of temperatures than in the factory.

Although refinement or calculation of the FT curve in the field helps calibrate the XO over a range of commonly encountered temperatures, it has been found that under some circumstances the field-calculated FT curve accumulates sufficient error that the mobile phone is unable to acquire the synchronization signals transmitted by a base station that are fundamental to establishing communication between the mobile phone and the base station. Although a mobile phone may make repeated attempts to acquire the base station synchronization signals, an inaccurate frequency reference will generally result in repeated acquisition failures. Rebooting the mobile phone may alleviate the problem. However, manually rebooting the mobile phone is inconvenient for the user. Also, as acquisition may fail for reasons other than a phone's inaccurate frequency reference, such as poor cell coverage, rebooting the phone as a solution is unlikely to immediately occur to a user. Further, rebooting is disruptive to the user experience.

It would be desirable to provide a way for a mobile phone to automatically and gracefully recover from acquisition failure due to an erroneous field-calculated FT curve.

### SUMMARY OF THE DISCLOSURE

Systems, methods and computer program products are disclosed for auto-recovery from acquisition failure in a portable computing device.

An exemplary method for auto-recovery from acquisition failure in a portable computing device (“PCD”) may include: applying temperature compensation to a crystal oscillator (“XO”) associated with radio frequency (“RF”) transceiver circuity of the PCD using a field-calculated frequency-temperature (“FT”) curve; attempting acquisition of an RF synchronization signal; in response to acquisition failure, determining whether a deviation between a field-calculated FT curve and a factory-set FT curve exceeds threshold criteria; in response to acquisition success, refining the field-calculated FT curve based on frequency error information; and in response to acquisition failure and a determination that the deviation exceeds the threshold criteria, replacing information defining the field-calculated FT curve with information defining the factory-set FT curve.

An exemplary system for auto-recovery from acquisition failure in a PCD may include circuitry configured to attempt acquisition of an RF synchronization signal, a temperature sensor, an XO associated with RF transceiver circuity of the PCD, and an XO manager. The XO manager may be configured to control a method comprising: applying temperature compensation to the XO using a field-calculated FT curve; in response to acquisition failure, determining whether a deviation between the field-calculated FT curve and a factory-set FT curve exceeds threshold criteria; in response to acquisition success, refining the field-calculated FT curve based on frequency error information; and in response to acquisition failure and a determination that the deviation exceeds the threshold criteria, replacing information defining the field-calculated FT curve with information defining the factory-set FT curve.

Another exemplary system for auto-recovery from acquisition failure in a PCD may include: means for applying temperature compensation to an XO associated with RF transceiver circuity of the PCD using a field-calculated FT curve; means for attempting acquisition of an RF synchronization signal; means for, in response to acquisition failure, determining whether a deviation between a field-calculated FT curve and a factory-set FT curve exceeds threshold criteria; means for, in response to acquisition success, refining the field-calculated FT curve based on frequency error information; and means for, in response to acquisition failure and a determination that the deviation exceeds the threshold criteria, replacing information defining the field-calculated FT curve with information defining the factory-set FT curve.

An exemplary computer program product for auto-recovery from acquisition failure in a PCD may include a computer-readable medium having stored thereon instructions that when executed by a processor control a method comprising: applying temperature compensation to an XO associated with RF transceiver circuity of the PCD using a field-calculated FT curve; attempting acquisition of an RF synchronization signal; in response to acquisition failure, determining whether a deviation between a field-calculated FT curve and a factory-set FT curve exceeds threshold criteria; in response to acquisition success, refining the field-calculated FT curve based on frequency error information; and in response to acquisition failure and a determination that the deviation exceeds the threshold criteria, replacing information defining the field-calculated FT curve with information defining the factory-set FT curve.

### BRIEF DESCRIPTION OF THE DRAWINGS

In the Figures, like reference numerals refer to like parts throughout the various views unless otherwise indicated. For reference numerals with letter character designations such as “102A” or “102B”, the letter character designations may differentiate two like parts or elements present in the same Figure. Letter character designations for reference numerals may be omitted when it is intended that a reference numeral to encompass all parts having the same reference numeral in all Figures.

FIG. 1 is a block diagram of system for auto-recovery from acquisition failure in a portable computing device (“PCD”), in accordance with exemplary embodiments.

FIG. 2 is a flow diagram illustrating a method for auto-recovery from acquisition failure in a PCD, in accordance with exemplary embodiments.

FIG. 3A is a flow diagram illustrating another method for auto-recovery from acquisition failure in a PCD, in accordance with exemplary embodiments.

FIG. 3B is a continuation of the flow diagram of FIG. 3A.

FIG. 4A is a flow diagram illustrating still another method for auto-recovery from acquisition failure in a PCD, in accordance with exemplary embodiments.

FIG. 4B is a continuation of the flow diagram of FIG. 4A.

FIG. 5 is a block diagram of a PCD, in accordance with exemplary embodiments.

FIG. 6 is a block diagram of a processor system, in accordance with exemplary embodiments.

### DETAILED DESCRIPTION

The word “exemplary” is used herein to mean “serving as an example, instance, or illustration.” The word “illustrative” may be used herein synonymously with “exemplary.” Any aspect described herein as “exemplary” is not necessarily to be construed as preferred or advantageous over other aspects.

It is known that an FT curve for temperature-compensating an XO may be expressed as a polynomial function or equation, such as Equation 1 below:

f(t)=c₃(t−t₀)³+c₂(t−t₀)²+c₁(t−t₀)+c₀

In Equation 1, f(t) represents the frequency error of an XO (in units of ppm) at a temperature t, where t0 is a reference temperature around which the curve is expanded and is typically a constant, such as room temperature (e.g., 30 C). The coefficients C0-C3 may be determined using methods well known to one of ordinary skill in the art. The coefficient C0 is a DC offset and is commonly set to a constant at the factory, but may be refined in the field. The coefficient C1 dominates the linear region of the FT curve and is commonly calculated in the field. The coefficient C2 is usually set to zero in all situations because of the following (Equation 2):

$${c}_{2} ≡ \frac{{d}^{2} f ( t )}{{d ( t )}^{2}} \approx 0$$

where d² is the second-order differential.

The coefficient C3 dominates temperature extremes. The coefficient C3 is not commonly set at the factory because it would be impractical to subject the XO (or a mobile phone containing the XO) to a wide range of temperatures in a factory calibration method. Rather, the coefficient C3 is commonly calculated in the field while the mobile phone is in operation and naturally experiencing a range of temperatures.

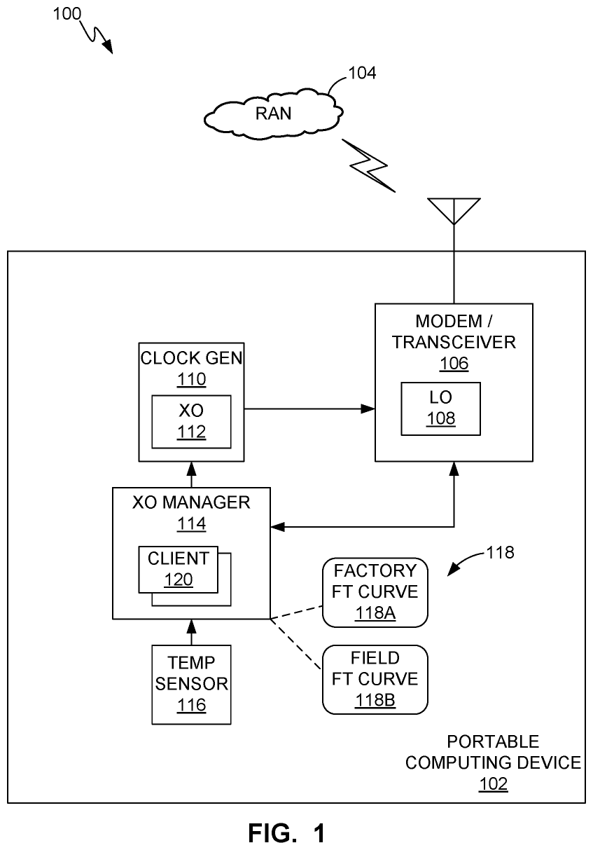

FIG. 1 illustrates a system 100 that includes a PCD 102, such as a mobile phone, and a radio access network (“RAN”) 104 that may be based upon any of various radio access technologies (“RATs”), such as, but not limited to, 2G, 3G, 4G, 5G, GNSS, etc. The RAN 104 may comprise a base station (e.g. eNB, gNB, etc.), among other elements. The PCD 102 includes a modem or transceiver 106 having one or more local oscillators (“LO”) 108 that require accurate frequency reference signals for proper operation. Such frequency reference signals may be provided by clock signal generation circuitry 110 that includes an XO 112.

An XO manager 114 may maintain one or more FT curves 118, each in accordance with above-described Equation 1. The FT curves 118 may include one or more factory-set FT curves 118A and one or more field-calculated FT curves 118B. Initially, i.e., when the PCD 102 leaves the factory, there may be as few as one FT curve 118 that was set in the factory. When the PCD 102 begins operating in the field, the one or more field-calculated FT curves 118B may be initialized by copying a factory-set FT curve 118A. However, as the PCD 102 continues to operate over time, the XO manager 114 may use measurements obtained from one or more temperature sensors 116 to refine or calibrate the one or more field-calculated FT curves 118B. During operation of the PCD 102, the XO 112 adjusts its oscillation frequency in response to temperature measurements and one or more of the field-calculated FT curves 118B.

A field calibration method may be performed, e.g., at intervals, or based on a triggering event, such as cell acquisition. In the field calibration method, the RAN 104, which employs associated radio access technology, measures the frequency of an RF signal it receives from the PCD 102 (i.e., an RF signal produced by a transmitter portion of the transceiver 106). The RAN 104 then estimates the frequency error between the frequency expected by the RAN 104 and the measured frequency of the RF signal received from the PCD 102. The RAN 104 transmits the frequency error information, also referred to as rotator information, to the PCD 102.

The XO manager 114 uses the frequency error information and temperature measured by the PCD 102 to re-calculate a field-calculated FT curve 118B, or if no field-calculated FT curves 118B yet exist, to calculate the first such field-calculated FT curve 118B. As a result of the foregoing field calibration method being repeatedly performed over the course of normal operation of the PCD 102 in the field, the field-calculated FT curve 118B may increasingly deviate from the factory-set FT curve 118A.

Although refinement or re-calculation of a field-calculated FT curve 118B generally helps compensate for XO frequency deviation over a wider range of temperatures than can be addressed in the factory setting, it has been found that under some circumstances the field-calculated FT curve 118B exhibits an amount of error that exceeds a threshold above which the PCD 102 is no longer able to successfully acquire base station synchronization signals.

It has been discovered in accordance with the present disclosure that errors in the field-calculated FT curve 118B for the PCD 102 or other such device can be attributed to at least one, or a combination of more than one, of the following factors:
(a) improper radio network behavior/high-frequency error;
(b) aging factor of the XO;
(c) the device being subject to extreme temperatures; and/or
(d) deviation in the factory XO calibration process from best practices (e.g., the factory may have re-used XO calibration data from a “golden device” or theoretical model, or applied averaged results from a sample lot of devices).

It has been found that the above factors can result in a difference of, for example, about 5 ppm between the field-calculated FT curve and the factory-set FT curve. It has also been found that a difference of 5 ppm or more commonly exceeds the error tolerance of the mobile phone for acquiring a cell signal in a frequency where the field-calculated FT curve 118B exhibits such a difference.

It should be noted that, in accordance with exemplary methods described below, there may be more than one factory-set FT curve 118A and more than one field-calculated FT curve 118B. For example, there may be one factory-set FT curve 118A and one field-calculated FT curve 118B for each technology (i.e., each RAT). The various field-calculated FT curves 118B may correspond to various frequency bands (e.g., 2G, 3G, 4G, 5G, GNSS, etc.) across multiple subscriber identification module (“SIM”) subscriptions for the PCD 102. These multiple field-calculated FT curves 118B are maintained/monitored by corresponding client entities 120 executing in, or otherwise embodied in, the XO manager 114.

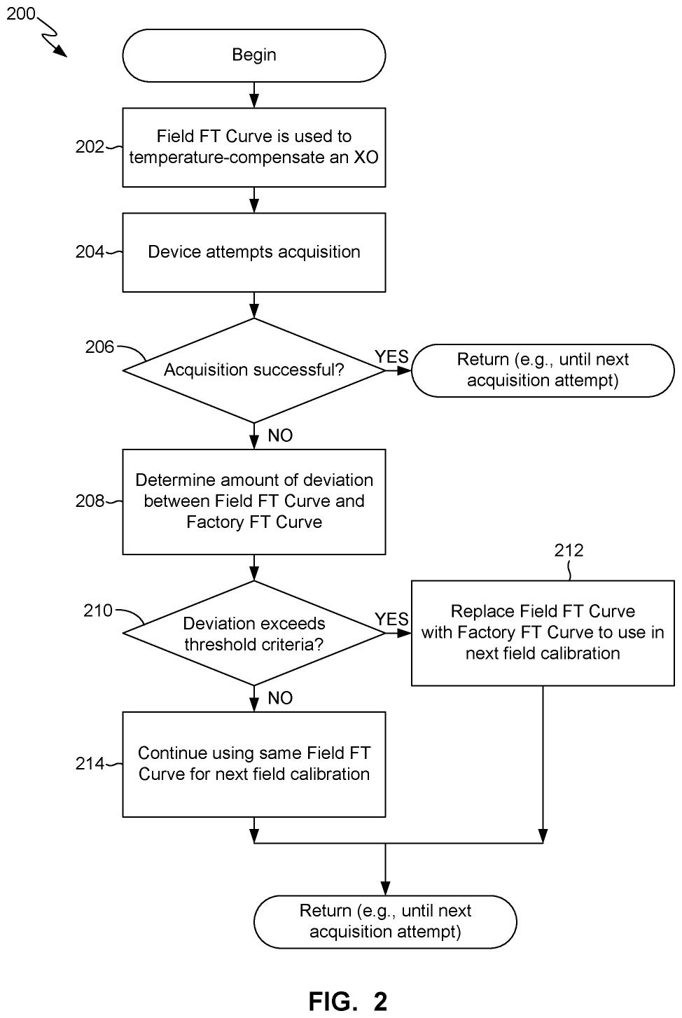

As illustrated in FIG. 2, a method 200 for auto-recovery from acquisition failure may be performed or controlled in the PCD 102 or other device. The XO manager 114 may include logic, such as a processor, state machine, etc., for controlling portions of method 200 and other methods described herein. The method 200 may involve or be predicated on using a field-calculated FT curve 118B to temperature-compensate the XO 112, as indicated by block 202. Temperature-compensating the XO 112 may occur essentially continuously throughout the operation of the PCD 102. Although not indicated in FIG. 2 for purposes of clarity, the method 200 initially begins with at least one factory-set FT curve 118A (“Factory FT Curve”) and at least one field-calculated FT curve 118B (“Field FT Curve”) stored in a manner accessible to the XO manager 114. Similarly, field calibration (i.e., calculation) of the FT curve 118B is not shown in FIG. 2 for purposes of clarity.

As indicated by block 204, the PCD 102 may attempt an acquisition. That is, the PCD 102 may attempt to acquire synchronization signals transmitted by a base station or other entity involved in wireless network communication. As the manner in which such a wireless communication device attempts acquisition is well understood by one of ordinary skill in the art, such aspects are not described herein.

As indicated by block 206, it is determined whether the attempted acquisition succeeded. If it is determined (block 206) that the attempted acquisition succeeded, the PCD 102 may return to or continue other operations, such as conventional operations or whatever operations it may have been performing before beginning method 200. The PCD 102 may return to such operations until, for example, it again attempts an acquisition, at which time the method 200 may begin again.

If it is determined (block 206) that the attempted acquisition failed, the amount of deviation between the Field FT Curve that is then being employed (e.g., in block 202) and the Factory FT Curve is determined, as indicated by block 208. As indicated by block 210, it is determined whether the amount of deviation exceeds a threshold. If it is determined (block 210) that the amount of deviation exceeds the threshold, information defining the Field FT Curve, including the coefficients C0-C3, is replaced with the corresponding information defining the Factory FT curve, as indicated by block 212. Following such replacement (block 212), the PCD 102 may return to or continue other operations (e.g., until such time as another acquisition may be attempted and the method 200 begun again).

If it is determined (block 210) that the amount of deviation does not exceed the threshold, the XO manager 114 may continue employing the same Field FT curve it had been employing before the method 200 was begun, as indicated by block 214. Thus, that same Field FT curve will continue to be employed in temperature-compensating the XO (block 202), and if another acquisition is attempted, that same Field FT curve will be employed when the method 200 is begun again.

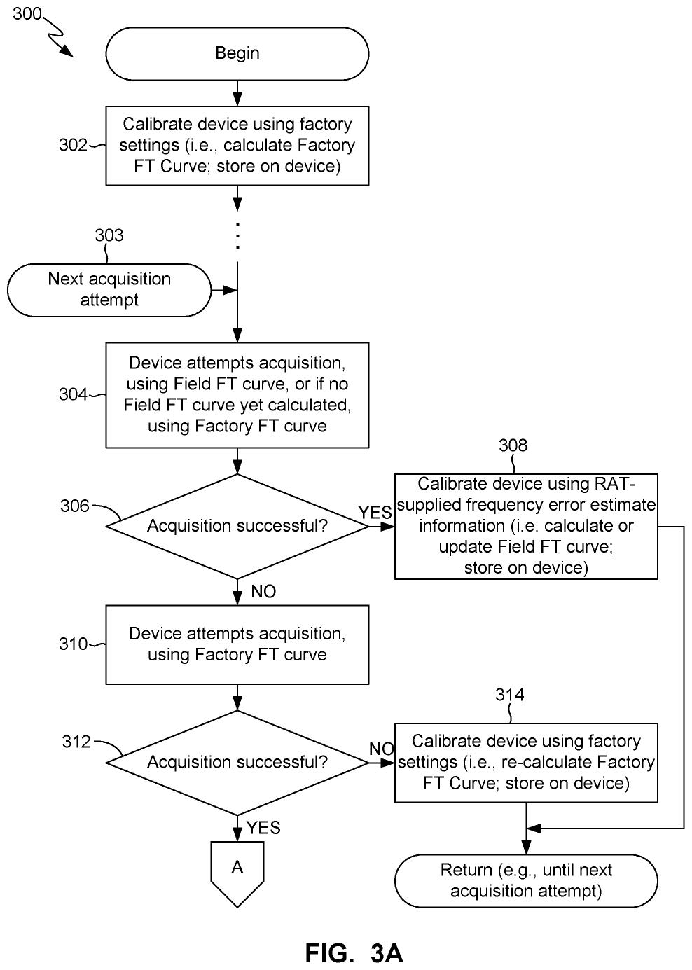

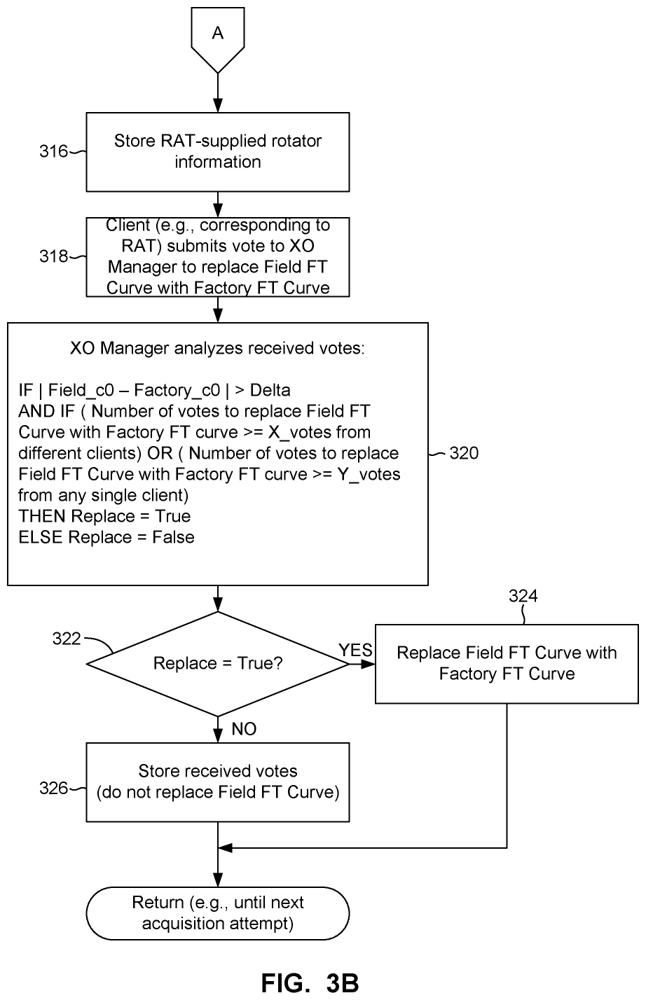

As illustrated in FIGS. 3A-3B, another method 300 for auto-recovery from acquisition failure may be performed or controlled in the PCD 102 or other device. A portion of the method 300 may be an example of a portion of the above-described method 200 (FIG. 2).

As indicated by block 302, the method 300 may begin with factory-calibrating the PCD 102 to provide the Factory FT Curve. As indicated by the ellipsis (“. . . ”) symbol between blocks 302 and 304, the remainder of the method 300 may be performed in the field. As indicated by block 304, the PCD 102 may attempt an acquisition, using the Field FT Curve. If no Field FT Curve yet exists (e.g., because the acquisition attempt is the first since the PCD 102 left the factory), the acquisition attempt may use the Factory FT Curve. As indicated by block 303, each time another acquisition is attempted, the method 300 may return to block 304.

As indicated by block 306, it is determined whether the acquisition succeeded. If it is determined (block 306) that the acquisition succeeded, calibration of the Field FT Curve may be performed in a conventional manner, as indicated by block 308. Commonly, the XO 112 receives frequency error information generated by the RAN 104 (FIG. 1). The manner in which the Field FT Curve may be calculated based on received frequency error information is well understood by one of ordinary skill in the art. Nevertheless, it may be noted that frequency-temperature data points comprising the frequency error information received at intervals from the RAN 104, along with contemporaneous temperature measurements, may be fit to a Field FT curve using well-known curve fitting techniques with the above-referenced Equation 1. If no Field FT Curve has yet been calculated, at least such two frequency-temperature points may be used to define an initial Field FT Curve. An existing Field FT Curve may be refined or re-calculated by fitting more frequency-temperature data points to refine the values of the coefficients, e.g., C0 and C1. For example, an existing Field FT Curve may be re-calculated after 15 or more frequency-temperature data points have been gathered. The re-calculated or newly calculated Field FT Curve (e.g., one or more of the coefficients C0-C3) is stored in the PCD 102. Following such calibration (block 308), the PCD 102 may return to or continue other operations (e.g., until such time as another acquisition may be attempted and the method 300 begun again).

If it is determined (block 306) that the first attempted acquisition (block 304) failed, the PCD 102 may again attempt acquisition, but this second time using the Factory FT Curve, as indicated by block 310. As indicated by block 312, it is determined whether this second attempted acquisition (block 310) failed. It should be noted that if an attempted acquisition using the Factory FT Curve fails, then the PCD 102 likely was not capable of operating properly in this respect when it left the factory. That is, the Factory FT curve was likely faulty. Accordingly, the PCD 102 may need to undergo a factory calibration procedure (e.g., performed by service personnel), resulting in a new Factory FT Curve being stored in the PCD 102 in place of the faulty Factory FT Curve, as indicated by block 314. Note that the acquisition attempt indicated by block 310 is a second acquisition attempt (the first being the acquisition attempt indicated by block 304) and uses the Factory FT Curve to virtually ensure successful acquisition (but for the unlikely possibility of a faulty Factory FT curve).

If it is determined (block 312) that the acquisition attempt (block 310) succeeded, then the following steps may be performed as described below with regard to FIG. 3B (following the off-page flow connector “A” from FIG. 3A to FIG. 3B). As indicated by block 316, the frequency error information generated by the RAN 104 may be stored for use in a further field calibration (i.e., re-calculation or refinement of the Field FT Curve) if the steps described below result in no immediate replacement of that Field FT Curve with the Factory FT Curve.

Further in response to the unsuccessful first acquisition attempt (block 306), an indication or vote is recorded in the XO manager 114, as indicated by block 318. The vote is specific to the client 120 (FIG. 1) to which the current acquisition attempt (block 310) related. As noted above, the PCD 102 may support multiple clients 120. In method 300, each time the XO manager 114 records a vote, it correspondingly records information identifying the client 120 to which the acquisition attempt related. Conceptually, the vote means that the underlying algorithm suggests that that client 120 may benefit from replacement of its Field FT Curve with the Factory FT Curve.

As indicated by block 320, the XO manager 114 may perform an analysis based in part on a calculated difference between the Field FT Curve and the Factory FT Curve and in part on the received votes. The portion of the analysis based on the calculated difference may include the following equation (Equation 3):

|Field_C0−Factory_C0|>Delta,

where Field_C0 is the DC offset in the Field FT curve in units of 2\hat{ }12 ppm, Factory_C0 is the DC offset in the Factory FT curve in units of 2\hat{ }12 ppm, and Delta is a constant in units of 2\hat{ }12 ppm. The value of Delta may be proportional to the age of the XO 112. For example, Delta may have a baseline value when the XO 112 is new (i.e., aged zero years) and may be incremented by a constant amount with each additional year of age. Although the baseline value and the increment may have any values, in an example in which the baseline value is 3 ppm and the increment is 0.7 ppm, the value of Delta may be selected to be 3.0 when the XO 112 is new, 3.7 when the XO 112 is aged one year, 4.4 when the XO 112 is aged two years, etc. The absolute value of the difference between the coefficient C0 in the Field FT curve and the coefficient C0 in the Factory FT curve may be determined and compared with Delta. If the absolute value of the difference between the coefficient C0 in the Field FT curve and the coefficient C0 in the Factory FT curve is greater than Delta, then the votes may nonetheless affect the decision whether to replace the Field FT Curve with the Factory FT Curve. Note that the analysis indicated by block 320 may be performed repeatedly, each time possibly taking into account another vote. That is, as the one or more clients 120 continue acquisition attempts, two or more votes may have accumulated at the time of the analysis.

If the absolute value of the difference between the coefficient C0 in the Field FT curve and the coefficient C0 in the Factory FT curve is greater than Delta, and if there are sufficient votes, then the result of the analysis indicates that the Field FT Curve is to be replaced with the Factory FT Curve. If the absolute value of the difference between the coefficient C0 in the Field FT curve and the coefficient C0 in the Factory FT curve is not greater than Delta, or if there are not sufficient votes, then the result of the analysis indicates that the Field FT Curve is not to be replaced with the Factory FT Curve. “Sufficient votes” may consist of, for example, at least “X_votes” associated with two or more different clients 120 or at least “Y_votes” from any single client 120. For example, X_votes may be 2, and Y_votes may be 5. Block 322 indicates determining the result of the analysis.

If it is determined (block 322) that the result of the analysis indicates that the Field FT Curve is to be replaced with the Factory FT Curve, then the replacement is performed, as indicated by block 324. Following such replacement (block 324), the PCD 102 may return to or continue other operations (e.g., until such time as another acquisition may be attempted and the method 300 begun again).

If it is determined (block 322) that the result of the analysis indicates that the Field FT Curve is not to be replaced with the Factory FT Curve, then the received vote is stored or recorded along with previously received votes. The PCD 102 then may return to or continue other operations (e.g., until such time as another acquisition may be attempted and the method 300 begun again). Although not shown for purposes of clarity, all recorded votes may be erased if the Field FT Curve is replaced (block 324) with the Factory FT Curve.

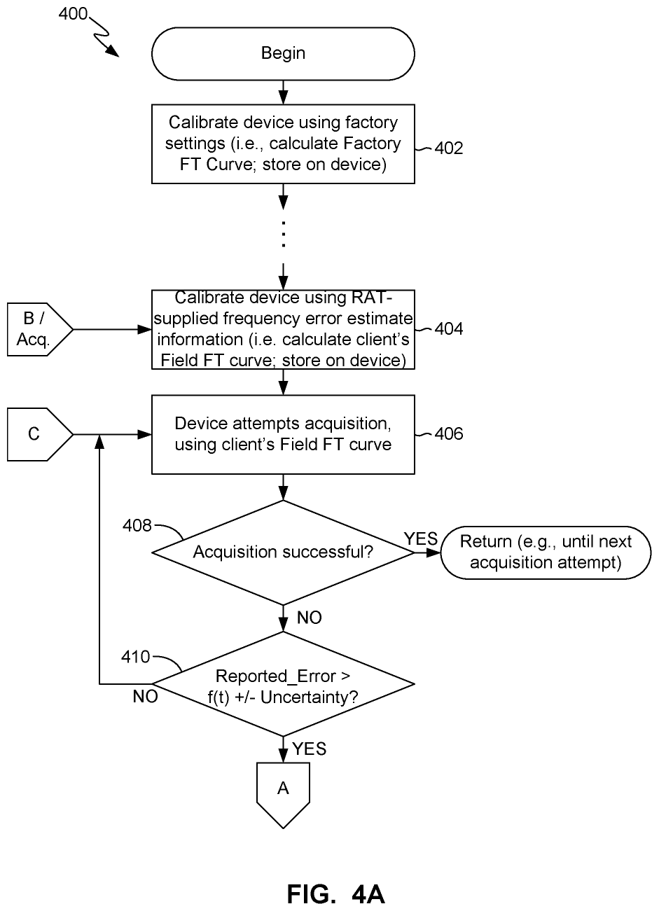

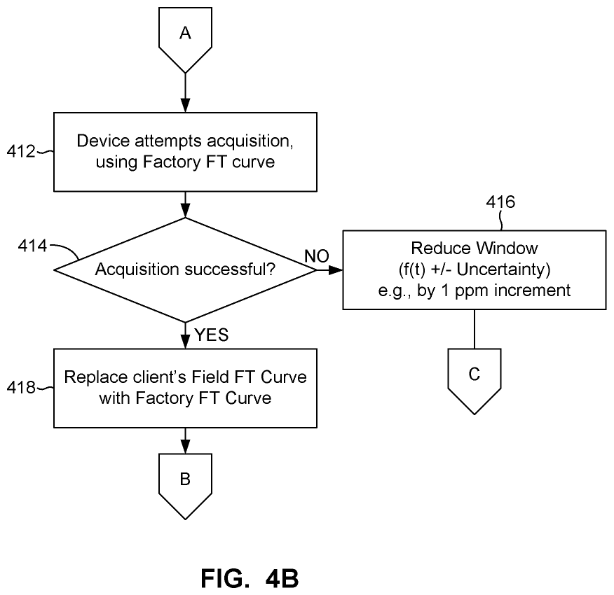

As illustrated in FIGS. 4A-4B, another method 400 for auto-recovery from acquisition failure may be performed or controlled in the PCD 102 or other device. A portion of the method 400 may be an example of a portion of the above-described method 200 (FIG. 2).

As indicated by block 402, the method 400 may begin with factory-calibrating the PCD 102 to provide the Factory FT Curve. As indicated by the ellipsis (“. . . ”) symbol between blocks 402 and 404, the remainder of the method 400 may be performed in the field.

As indicated by block 404, calibration of the Field FT Curve may be performed in a conventional manner, using RAT or RAN-supplied frequency error information. Although not shown for purposes of clarity, the PCD 102 may have received the frequency error information following a previously attempted (successful) acquisition. In FIG. 4A, the off-page flow connector “B/Acq” indicates not only process flow from FIG. 4B back to block 404 but also that each time another acquisition is attempted the method 400 may return to block 404.

As described below, there may be two or more Field FT Curves (e.g., field-calculated FT curves 118B). Each Field FT Curve is associated with one of the clients 120, and each client 120 is associated with a different technology (i.e., RAT).

As indicated by block 406, the PCD 102 may attempt an acquisition, using the Field FT Curve relating to the client and technology associated with the acquisition attempt. As indicated by block 408, it is determined whether the acquisition succeeded. If it determined (block 408) that the acquisition succeeded, the PCD 102 may return to or continue other operations (e.g., until such time as another acquisition may be attempted and the method 400 begun again).

As indicated by block 410, if it is determined (block 408) that the acquisition attempt (block 406) failed, the XO manager 114 may perform a frequency error analysis. The frequency error analysis may include computing the following equation (Equation 4):

Reported_Error>f(t)+/−Uncertainty,

where Reported_Error is the frequency error information reported by the RAN 104 to the PCD 102 (FIG. 1) and is a measurement of frequency error resulting from use of the Field FT Curve, f(t) is the computed value (using Equation 1) of the Field FT Curve at the then-measured temperature t, and Uncertainty is a constant that defines a window around f(t). That is, the quantity (f(t)+/−Uncertainty) may be referred to as a window of uncertainty around f(t). The Field FT Curve f(t) in Equation 4 is that which is associated with the one of clients 120 to which the acquisition attempt (block 406) relates. The value of Uncertainty may be directly related to factors including XO age, hysteresis, base station error etc. That is, the value of Uncertainty increases with increasing XO age, hysteresis, base station error, etc. Accordingly, the window of uncertainty around f(t) may increase with increasing XO age, hysteresis, base station error, etc. Although Uncertainty may have any value, in an example in which the Field FT Curve f(t) evaluates to 8 ppm at the then-measured temperature t, and the value of Uncertainty is 2 ppm, the window around f(t) is the range between 6 and 10 ppm. In Equation 4, the greater-than symbol “>” represents a condition of exceeding or being outside the window around f(t). Therefore, in an example in which the value of Uncertainty is 2 ppm and the value of Reported_Error is 4 ppm, Equation 4 would evaluate to “true” or “yes,” i.e., Reported_Error exceeds the window around f(t) because 4 ppm is not between 6 and 10 ppm. However, in an example in which the value of Uncertainty is 2 ppm and the value of Reported_Error is 7 ppm, Equation 4 would evaluate to “false” or “no,” i.e., Reported_Error would be within the window around f(t) because 4 ppm is between 6 and 10 ppm.

If it is determined (block 410) that Equation 4 is false, i.e., the value of Reported_Error is within the window around f(t), then the method 400 continues as described above with regard to block 406. If it is determined (block 410) that Equation 4 is true, i.e., the value of Reported_Error is outside the window around f(t), then the method flow follows the off-page connector “A” from FIG. 4A to FIG. 4B, and method 400 continues at block 412.

As indicated by block 412, the PCD 102 may attempt an acquisition using the Factory FT Curve. Note that the acquisition attempt indicated by block 412 is a second acquisition attempt (the first being the acquisition attempt indicated by block 408) and uses the Factory FT Curve to virtually ensure successful acquisition. It may also be noted that in method 400 the first acquisition attempt (block 408) occurs before determining the error value or window (f(t)+/−Uncertainty), and the error value is not determined unless the first acquisition attempt fails.

As indicated by block 414, it is determined whether the acquisition attempt (block 412) succeeded. The embodiment represented by method 400 considers that an acquisition attempt using the Factory FT Curve may fail due to some other cause, such as, for example, poor cell coverage. Accordingly, if it is determined (block 414) that the acquisition attempt (block 412) failed, then the value of Uncertainty is reduced, as indicated by block 416, and the method continues (following the off-page connector “C” from FIG. 4B back to FIG. 4A) at block 406 as described above.

If it is determined (block 414) that the acquisition attempt (block 412) succeeded, then the Field FT Curve is replaced with the Factory FT Curve, as indicated by block 418. Note that the Field FT Curve and Factory FT Curve in block 418 are those which are associated with the one of clients 120 to which the acquisition attempts (blocks 408 and 412) related. That is, the Field FT Curve and Factory FT Curve in block 418 are technology (RAT)-specific. Following the off-page connector “B” from FIG. 4B back to FIG. 4A, method 400 may continue as described above with regard to block 404. That is, with the erroneous technology-specific Field FT Curve having been replaced with the technology-specific Factory FT Curve, the XO manager 114 may continue to re-calculate or refine that Field FT curve.

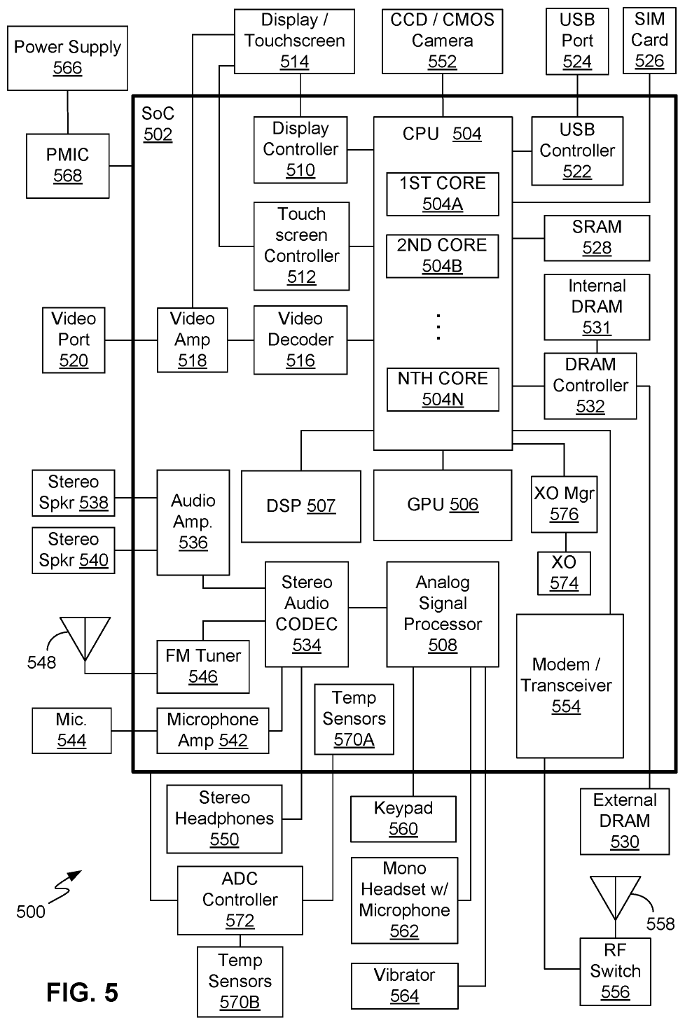

As illustrated in FIG. 5, exemplary embodiments of systems and methods for sensor data storage may be embodied in a PCD 500. The PCD 500 includes a system-on-a-chip (“SoC”) 502. The SoC 502 may include a CPU 504, a GPU 506, a DSP 507, an analog signal processor 508, or other processors. The CPU 504 may include multiple cores, such as a first core 504A, a second core 504B, etc., through an Nth core 504N.

A display controller 510 and a touchscreen controller 512 may be coupled to the CPU 504. A touchscreen display 514 external to the SoC 502 may be coupled to the display controller 510 and the touchscreen controller 512. The PCD 500 may further include a video decoder 516 coupled to the CPU 504. A video amplifier 518 may be coupled to the video decoder 516 and the touchscreen display 514. A video port 520 may be coupled to the video amplifier 518. A universal serial bus (“USB”) controller 522 may also be coupled to CPU 504, and a USB port 524 may be coupled to the USB controller 522. A subscriber identity module (“SIM”) card 526 may also be coupled to the CPU 504.

One or more memories may be coupled to the CPU 504. The one or more memories may include both volatile and non-volatile memories. Examples of volatile memories include static random access memory (“SRAM”) 528 and dynamic RAMs (“DRAM”s) 530 and 531. Such memories may be external to the SoC 502, such as the DRAM 530, or internal to the SoC 502, such as the DRAM 531. A DRAM controller 532 coupled to the CPU 504 may control the writing of data to, and reading of data from, the DRAMs 530 and 531. In other embodiments, such a DRAM controller may be included within a processor, such as the CPU 504.

A stereo audio CODEC 534 may be coupled to the analog signal processor 508. Further, an audio amplifier 536 may be coupled to the stereo audio CODEC 534. First and second stereo speakers 538 and 540, respectively, may be coupled to the audio amplifier 536. In addition, a microphone amplifier 542 may be coupled to the stereo audio CODEC 534, and a microphone 544 may be coupled to the microphone amplifier 542. A frequency modulation (“FM”) radio tuner 546 may be coupled to the stereo audio CODEC 534. An FM antenna 548 may be coupled to the FM radio tuner 546. Further, stereo headphones 550 may be coupled to the stereo audio CODEC 534. Other devices that may be coupled to the CPU 504 include a digital (e.g., CCD or CMOS) camera 552.

A modem or RF transceiver 554 may be coupled to the analog signal processor 508. The modem/transceiver 554 may be an example of the above-described modem/transceiver 106 (FIG. 1). An RF switch 556 may be coupled to the RF transceiver 554 and an RF antenna 558. In addition, a keypad 560, a mono headset with a microphone 562, and a vibrator device 564 may be coupled to the analog signal processor 508.

A power supply 566 may be coupled to the SoC 502 via a power management integrated circuit (“PMIC”) 568. The power supply 566 may include a rechargeable battery or a DC power supply that is derived from an AC-to-DC transformer connected to an AC power source.

The SoC 502 may have one or more internal or on-chip thermal sensors 570A and may be coupled to one or more external or off-chip thermal sensors 570B. An analog-to-digital converter (“ADC”) controller 572 may convert voltage drops produced by the thermal sensors 570A and 570B to digital signals. Thermal sensors 570A and 570B may be examples of the temperature sensor 116 described above with regard to FIG. 1.

The touch screen display 514, the video port 520, the USB port 524, the camera 552, the first stereo speaker 538, the second stereo speaker 540, the microphone 544, the FM antenna 548, the stereo headphones 550, the RF switch 556, the RF antenna 558, the keypad 560, the mono headset 562, the vibrator 564, the thermal sensors 550B, the ADC controller 552, the PMIC 568, the power supply 566, the DRAM 530, and the SIM card 526 are external to the SoC 502 in this exemplary embodiment. It will be understood, however, that in other embodiments one or more of these devices may be included in such an SoC.

The SoC 502 may include an XO 574 and an XO manager 576, which may be examples of the XO 112 and XO manager 114, respectively, described above with regard to FIG. 1. Although for purposes of clarity the XO 574 and XO manager 576 are depicted in FIG. 5 separately from the modem/transceiver 554, the XO 574, XO manager 576, or both may be included in the modem/transceiver 554. The modem/transceiver 554 may be an example of the modem/transceiver 106 described above with regard to FIG. 1. As understood by one of ordinary skill in the art, the modem/transceiver 554, or the modem/transceiver 554 in combination with other elements, such as the CPU 504, may be an example of circuitry configured to attempt acquisition of RF synchronization signals. One of the above-referenced thermal sensors 570B may be configured in thermal communication with the XO 112, such as in the same physical package with the XO 112 (FIG. 1), such that a sensed temperature represents a temperature experienced by the XO 112. More generally, the organization and arrangement of SoC elements with respect to other elements is not limited to the example shown in FIG. 5.

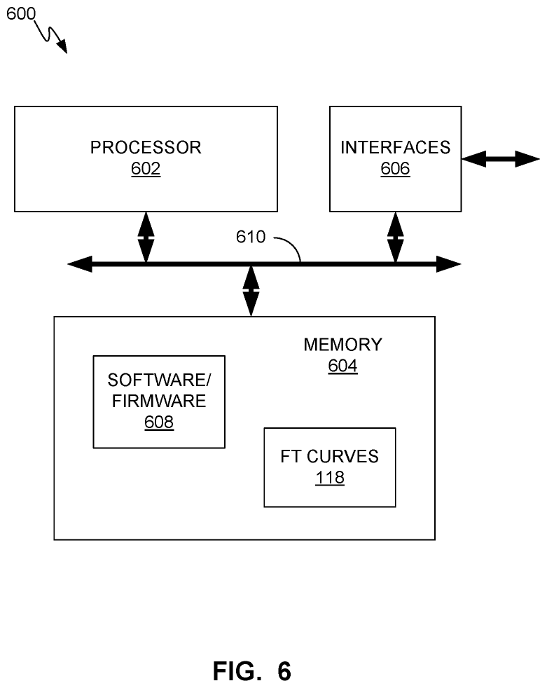

FIG. 6 illustrates a processor system 600. The processor system 600 may include a processor 602, a memory 604, data interfaces 606, or other elements (not shown) that are characteristic of a system of computer-related logic that operates under the control of software (or firmware, etc.) 608. A bus 610 or similar interconnect structure may provide data communication among the processor 602, memory 604, interfaces 606, or other elements. The data interfaces 606 may be coupled to other SoC or PCD elements, such as a system interconnect fabric (not shown). The above-described methods 200 (FIG. 2) 300 (FIGS. 3A-3B) and 400 (FIGS. 4A-4B) may be controlled or achieved through the execution of the software 608 by the processor 602. Execution of the software 608 configures the circuitry of the processor 602 accordingly, and thus the configured processor 602 may be an example of the above-described XO manager 114 (FIG. 1) or 574 (FIG. 5). The software 608 may include the clients 120 (FIG. 1). The XO manager 114, a client 120, etc., may correspond to a thread of execution on a processor.

Although for purposes of clarity the software 608 is shown as stored or residing in the memory 604 as a discrete or unitary element, one of ordinary skill in the art understands that the software 608 may be retrieved from the memory 604 or other source(s), and executed by the processor 602 or other processor in accordance with conventional computing principles, such as on an as-needed basis, in portions such as instructions, segments, objects, files, etc., and that the software 608 may be distributed among more than one such memory or other storage source. The memory 604 or other memory from which the software 608 is retrieved for execution may be volatile (e.g., DRAM) or non-volatile (e.g., flash). Such memories may include those described above with regard to FIG. 5. Similarly, the processing task or tasks represented by the execution of the software 608 may be distributed among multiple processors, such as the CPU 504, DSP 507, etc., described above with regard to FIG. 5, or other processors. The FT curves 118 described above with regard to FIG. 1 may be stored in the memory 604 or other such memories. The memory 604 or other such memory or storage medium having the software 608 or a portion thereof stored thereon in computer-readable form may be an example of a “computer program product,” “computer-readable medium,” etc., as such terms are understood in the patent lexicon.

Although in FIG. 6 the configured processor 602 is an example of an XO manager, in other embodiments an XO manager alternatively may be embodied in other computer-related logic (i.e., circuitry). Such computer-related logic may include, for example, application specific integrated circuits (ASICs), field-programmable gate arrays (FPGAs), etc.

Alternative embodiments will become apparent to one of ordinary skill in the art to which the invention pertains without departing from its spirit and scope. Therefore, although selected aspects have been illustrated and described in detail, it will be understood that various substitutions and alterations may be made therein without departing from the spirit and scope of the present invention, as defined by the following claims.

What is claimed is:

1. A method for auto-recovery from acquisition failure in a portable computing device (“PCD”), comprising:
applying temperature compensation to a crystal oscillator associated with radio frequency (“RF”) transceiver circuity of the PCD using a field-calculated frequency-temperature (“FT”) curve responsive to a temperature measurement;
attempting acquisition of an RF synchronization signal;
in response to an acquisition failure, determining whether a deviation between the field-calculated FT curve and a factory-set FT curve exceeds threshold criteria;
in response to the acquisition failure and a determination that the deviation exceeds the threshold criteria, replacing information defining the field-calculated FT curve with information defining the factory-set FT curve; and
in response to an acquisition success, refining the field-calculated FT curve based on frequency error information.

2. The method of claim 1, wherein attempting acquisition comprises:
attempting a first acquisition using the field-calculated FT curve; and
attempting a second acquisition using the factory-calculated FT curve in response to a failure of the first acquisition.

3. The method of claim 2, wherein determining whether the deviation between the field-calculated FT curve and the factory-set FT curve exceeds threshold criteria is performed in response to the failure of the first acquisition and a success of the second acquisition.

4. The method of claim 3, wherein determining whether the deviation exceeds threshold criteria comprises:
determining a difference between a DC offset in the field-calculated FT curve and a DC offset in the factory-set FT curve; and
comparing the difference with a threshold value.

5. The method of claim 4, wherein determining whether the deviation between the field-calculated FT curve and the factory-set FT curve exceeds threshold criteria is based on votes received from a plurality of clients, each client corresponding to a different radio access technology involved in an attempted acquisition.

6. The method of claim 4, wherein determining whether the deviation exceeds threshold criteria comprises computing an equation:

|Field_C0−Factory_C0|>Delta,
wherein Field_C0 is the DC offset in the field-calculated FT curve, Factory_C0 is the DC offset in the factory-set FT curve, and Delta is a constant based on at least crystal oscillator age.

7. The method of claim 1, wherein the field-calculated FT curve is one of a plurality of field-calculated FT curves, each corresponding to a different radio access technology involved in an attempted acquisition, and wherein determining whether the deviation between the field-calculated FT curve and the factory-set FT curve exceeds threshold criteria comprises:
determining a measured frequency error resulting from use of the field-calculated FT curve;
determining a window around a computed value of the field-calculated FT curve at a measured temperature; and
comparing the measured frequency error with the window.

8. The method of claim 7, wherein the window is based on at least crystal oscillator age.

9. The method of claim 7, wherein attempting acquisition comprises:
attempting a first acquisition using the field-calculated FT curve before determining the measured frequency error and determining the window, wherein determining the measured frequency error and determining the window are performed in response to a failure of the first acquisition; and
attempting a second acquisition using the factory-calculated FT curve after determining the measured frequency error and determining the window, wherein replacing the information defining the field-calculated FT curve with the information defining the factory-set FT curve is performed in response to success of the second acquisition.

10. The method of claim 9, further comprising:
reducing the window in response to a failure of the second acquisition; and
in response to reducing the window, repeating the steps of attempting the first acquisition using the field-calculated FT curve, determining the measured frequency error and determining the window in response to failure of the first acquisition, and comparing the measured frequency error with the window.

11. A system for auto-recovery from acquisition failure in a portable computing device (“PCD”), comprising:
circuitry configured to attempt acquisition of a radio frequency (“RF”) synchronization signal;
a crystal oscillator associated with RF transceiver circuity of the PCD; and
a crystal oscillator manager configured to control a method comprising:
applying temperature compensation to the crystal oscillator using a field-calculated frequency-temperature (“FT”) curve responsive to a temperature measurement;
in response to acquisition failure, determining whether a deviation between the field-calculated FT curve and a factory-set FT curve exceeds threshold criteria;
in response to acquisition failure and a determination that the deviation exceeds the threshold criteria, replacing information defining the field-calculated FT curve with information defining the factory-set FT curve; and
in response to acquisition success, refining the field-calculated FT curve based on frequency error information.

12. The system of claim 11, wherein attempting acquisition comprises:
attempting a first acquisition using the field-calculated FT curve; and
attempting a second acquisition using the factory-calculated FT curve in response to a failure of the first acquisition.

13. The system of claim 12, wherein determining whether the deviation between the field-calculated FT curve and the factory-set FT curve exceeds threshold criteria is performed in response to success of the second acquisition.

14. The system of claim 13, wherein determining whether the deviation exceeds threshold criteria comprises:
determining a difference between a DC offset in the field-calculated FT curve and a DC offset in the factory-set FT curve; and
comparing the difference with a threshold value.

15. The system of claim 14, wherein determining whether the deviation between the field-calculated FT curve and the factory-set FT curve exceeds threshold criteria is based on votes received from a plurality of clients, each client corresponding to a different radio access technology involved in an attempted acquisition.

16. The system of claim 14, wherein determining whether the deviation exceeds threshold criteria comprises computing an equation:

|Field_C0−Factory_C0|>Delta,
wherein Field_C0 is the DC offset in the field-calculated FT curve, Factory_C0 is the DC offset in the factory-set FT curve, and Delta is a constant based on at least crystal oscillator age.

17. The system of claim 11, wherein the field-calculated FT curve is one of a plurality of field-calculated FT curves, each corresponding to a different radio access technology involved in an attempted acquisition, and wherein determining whether the deviation between the field-calculated FT curve and the factory-set FT curve exceeds threshold criteria comprises:
determining a measured frequency error resulting from use of the field-calculated FT curve;
determining a window around a computed value of the field-calculated FT curve at a measured temperature; and
comparing the measured frequency error with the window.

18. The system of claim 17, wherein the window is based on crystal oscillator age.

19. The system of claim 17, wherein attempting acquisition comprises:
attempting a first acquisition using the field-calculated FT curve before determining the measured frequency error and determining the window, wherein determining the measured frequency error and determining the window are performed in response to a failure of the first acquisition; and
attempting a second acquisition using the factory-calculated FT curve after determining the measured frequency error and determining the window, wherein replacing the information defining the field-calculated FT curve with the information defining the factory-set FT curve is performed in response to success of the second acquisition.

20. The system of claim 19, further comprising:
reducing the window in response to a failure of the second acquisition; and
in response to reducing the window, repeating the steps of attempting the first acquisition using the field-calculated FT curve, determining the measured frequency error and determining the window in response to failure of the first acquisition, and comparing the measured frequency error with the window.

21. A system for auto-recovery from acquisition failure in a portable computing device (“PCD”), comprising:
means for applying temperature compensation to a crystal oscillator associated with radio frequency (“RF”) transceiver circuity of the PCD using a field-calculated frequency-temperature (“FT”) curve responsive to a temperature measurement;
means for attempting acquisition of an RF synchronization signal;
means for, in response to an acquisition failure, determining whether a deviation between the field-calculated FT curve and a factory-set FT curve exceeds threshold criteria;
means for, in response to acquisition failure and a determination that the deviation exceeds the threshold criteria, replacing information defining the field-calculated FT curve with information defining the factory-set FT curve; and
means for, in response to an acquisition success, refining the field-calculated FT curve based on frequency error information.

22. The system of claim 21, wherein the means for attempting acquisition comprises:
means for attempting a first acquisition using the field-calculated FT curve; and
means for attempting a second acquisition using the factory-calculated FT curve in response to a failure of the first acquisition;
wherein the means for determining whether the deviation between the field-calculated FT curve and the factory-set FT curve exceeds threshold criteria operates in response to failure of the first acquisition and success of the second acquisition.

23. The system of claim 22, wherein the means for determining whether the deviation exceeds threshold criteria comprises:
means for determining a difference between a DC offset in the field-calculated FT curve and a DC offset in the factory-set FT curve; and
comparing the difference with a threshold value.

24. The system of claim 23, wherein the means for determining whether the deviation between the field-calculated FT curve and the factory-set FT curve exceeds threshold criteria operates based on votes received from a plurality of clients, each client corresponding to a different radio access technology involved in an attempted acquisition.

25. The system of claim 21, wherein the field-calculated FT curve is one of a plurality of field-calculated FT curves, each corresponding to a different radio access technology involved in an attempted acquisition, and wherein the means for determining whether the deviation between the field-calculated FT curve and the factory-set FT curve exceeds threshold criteria comprises:
means for determining a measured frequency error resulting from use of the field-calculated FT curve;
means for determining a window around a computed value of the field-calculated FT curve at a measured temperature; and
means for comparing the measured frequency error with the window.

26. A computer program product for auto-recovery from acquisition failure in a portable computing device (“PCD”), the computer program product comprising a computer-readable medium having stored thereon instructions that when executed on a processor control a method comprising:
applying temperature compensation to a crystal oscillator associated with radio frequency (“RF”) transceiver circuity of the PCD using a field-calculated frequency-temperature (“FT”) curve responsive to a temperature measurement;
attempting acquisition of an RF synchronization signal;
in response to an acquisition failure, determining whether a deviation between the field-calculated FT curve and a factory-set FT curve exceeds threshold criteria;
in response to acquisition failure and a determination that the deviation exceeds the threshold criteria, replacing information defining the field-calculated FT curve with information defining the factory-set FT curve; and
in response to an acquisition success, refining the field-calculated FT curve based on frequency error information.

27. The computer program product of claim 26, wherein attempting acquisition comprises:
attempting a first acquisition using the field-calculated FT curve; and
attempting a second acquisition using the factory-calculated FT curve in response to a failure of the first acquisition;
wherein determining whether the deviation between the field-calculated FT curve and the factory-set FT curve exceeds threshold criteria is performed in response to failure of the first acquisition and success of the second acquisition.

28. The computer program product of claim 27, wherein determining whether the deviation exceeds threshold criteria comprises:
determining a difference between a DC offset in the field-calculated FT curve and a DC offset in the factory-set FT curve; and
comparing the difference with a threshold value.

29. The computer program product of claim 28, wherein the determining whether the deviation between the field-calculated FT curve and the factory-set FT curve exceeds threshold criteria is based on votes received from a plurality of clients, each client corresponding to a different radio access technology involved in an attempted acquisition.

30. The computer program product of claim 26, wherein the field-calculated FT curve is one of a plurality of field-calculated FT curves, each corresponding to a different radio access technology involved in an attempted acquisition, and wherein determining whether the deviation between the field-calculated FT curve and the factory-set FT curve exceeds threshold criteria comprises:
determining a measured frequency error resulting from use of the field-calculated FT curve;
determining a window around a computed value of the field-calculated FT curve at a measured temperature; and
comparing the measured frequency error with the window.
